(19) United States
(12) Patent Application Publication
(10) Pub. No.: US 2006/0082979 A1
(43) Pub. Date: Apr. 20, 2006

(54) Installation device and installation assembly comprising said installation device

(76) Inventors: Wolfgang Brandl, Amberg (DE); Klaus Busch, Amberg (DE); Steger Reinhard, Sulzbach-Rosenberg (DE)

Correspondence Address: HARNESS, DICKEY & PIERCE, P.L.C., P.O.BOX 8910, RESTON, VA, 20195, US

(21) Appl. No.: 10/545,376

(22) PCT Filed: Jan. 29, 2004
(86) PCT No.: PCT/EP04/00812

§ 371 Date: Aug. 12, 2005

(30) Foreign Application Priority Data
Feb. 14, 2003 (EP) 03003447.4

(51) Int. Cl. H05K 7/14

(52) U.S. Cl. 361/729; 361/733

(57) ABSTRACT

An installation device and an installation assembly including at least one installation device are disclosed, which can be used in conjunction with various connection technologies and also be incorporated in different wiring systems. One connection side of the installation device is provided with a contact element, which is compatible with both a mating contact element of a connection device that can be positioned on the connection side and an additional mating contact element of an additional connection device that can be located on the connection side, but differs from the first connection device.

This application is the national phase under 35 U.S.C. § 371 of PCT International Application No. PCT/EP2004/000812 which has an International filing date of Jan. 29, 2004, which designated the United States of America and which claims priority on European Patent Application number EP 03003447.4 filed Feb. 14, 2003, the entire contents of which are hereby incorporated herein by reference.

### FIELD

The invention generally relates to a service or installation device and/or a service or installation assembly having at least one service or installation device.

### BACKGROUND

WO 99/23737 discloses a modular load feeder which is composed of a feeder assembly and a base lower part having integrated line and/or bus sections. The base lower part can in this case be extended to form a modular carrier system having a line system and a bus system by arranging further physically identical base lower parts in a row and making contact with them for the purpose of accommodating further feeder assemblies or input and output assemblies.

### SUMMARY

An object of at least one embodiment of the present invention is to specify a service or installation device and a service or installation assembly having at least one service or installation device which are suitable, on the one hand, for using different connection techniques and, on the other hand, for being incorporated in different wiring systems.

At least one object may be achieved by a service device and/or a service assembly in accordance with at least one embodiment of the invention.

An embodiment of the service device includes at least one contact device, arranged on one connection side and dedicated to the device, compatible both with an opposing contact device of a connection apparatus which can be arranged on the connection side and with an opposing contact device of a further connection apparatus. The further connection apparatus can be arranged on the connection side but is different than the connection apparatus. Further, using the contact devices which are designed to match the respective opposing contact devices, optionally firstly connection apparatuses can use different connection techniques for conductors which can be connected thereto or secondly different wiring systems having main current and/or auxiliary current conductor tracks to be electrically and mechanically coupled directly to the service device using simple methods/devices.

With regard to the service assembly having at least one service device, which has in each case one contact device on different connection sides, connection apparatuses are included which can be arranged thereon but are different than one another, having an opposing contact device designed to be compatible with the corresponding contact device and designed to be integral with the contact device or capable of being combined with one another such that, per connection side, one interface is created which ensures assembly integration. This is done without the use of an adapter. In particular, different connection apparatuses, which can optionally be arranged on the service device and contact-connected to it, can use different connection techniques for power lines or different wiring systems having main current and/or auxiliary current conductor tracks.

In at least one embodiment, at least one third contact device, compatible with a third opposing contact device of a third connection apparatus which can be arranged on the one connection side, may be advantageously integrated on one connection side of the service device. The third connection apparatus, in particular in the form of an alarm and/or control module, can also in this case be attached and contact-connected without the use of an adapter, i.e. directly to the service device or to the service assembly. As such, depending on the application, the desired connection apparatus using the corresponding connection technique can be provided.

### BRIEF DESCRIPTION OF THE DRAWINGS

The invention and advantageous refinements in accordance with features of the further claims will be explained in more detail below with reference to example embodiments illustrated in the drawings; in which:

FIGS. 1 and 2 each show schematic illustrations of a service device as part of a service assembly in different embodiments;

FIGS. 3 and 4 each show schematic illustrations of a service assembly in the form of a service system in different embodiments;

FIGS. 5 to 19 show perspective illustrations of designs of two service devices as part of a service assembly; and

FIGS. 20 and 21 show a schematic illustration and, respectively, a perspective illustration of contact elements and opposing contact elements.

### DETAILED DESCRIPTION OF THE EXAMPLE EMBODIMENTS

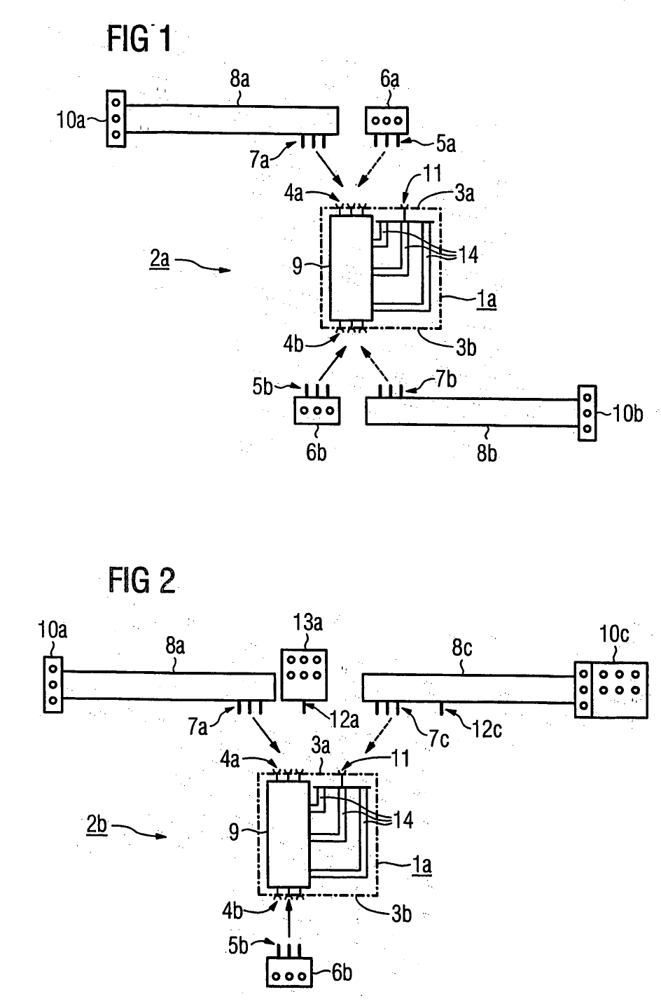

FIG. 1 shows an electrical service device 1a as part of a service assembly 2a which is provided on one connection side 3a with a contact element 4a. The contact element 4a is in this case designed to be compatible with, i.e. to fit together with, an opposing contact element 5a of a connection apparatus 6a which can be arranged on the connection side 3a. The contact element 4a is likewise compatible with a further opposing contact element 7a of a further connection apparatus 8a, which can be arranged on the connection side 3a but is different than the connection apparatus 6a. In this case, the use of different connection and/or wiring systems is ensured using simple devices/methods.

In one advantageous refinement of at least one embodiment, the service device 1a is provided on a further connection side 3b with a further contact element 4b which is likewise compatible with an opposing contact element 5b of a connection apparatus 6b and with a further opposing contact element 7b of a further connection apparatus 8b which is, however, different than the connection apparatus 6b. The connection apparatuses 6a, 6b or 8a, 8b with which contact can be made can also be mechanically fixed in each case per se to the connection sides 3a, 3b.

The modular design of the service assembly 2a is produced by the connection apparatus 6a, 6b, which is in the form of a connection unit, in particular in the form of a contact module, or the further connection apparatus 8a, 8b (which can be in the form of a contact rail or busbar system) being isolated from the service device 1a which has at least one electrical functional unit 9. An interface, which ensures the compatibility of the connection apparatuses 6a, 6b or 8a, 8b and the functional unit 9, having a uniform design of the contact element 4a, 4b and of the opposing contact element 5a, 5b or 7a, 7b. Thus, they supplement one another ensures that direct contact is made between the functional unit 9 of the service device 1a and the replaceable and removable contact modules as well as the contact rail system or busbar system for a main circuit and/or auxiliary circuit. In the context of embodiments of the invention, the main circuit and/or the auxiliary circuit may also include, in addition to active conductors, such as external, control and/or neutral conductors, inactive conductors, i.e., for example, a protective conductor.

The connection apparatuses 6a, 6b, which are provided in the form of contact modules, are designed for device lines to be connected thereto on the output side for the purpose of supplying power to a load element. On the other hand, the further connection apparatuses 8a, 8b act as the busbar system for the main circuit and, as such, supply main current to the service device 1a or to the service assembly 2a via a corresponding main current feed line 10a, 10b.

The service device 1a also advantageously has at least one third contact element 11, which is arranged on the connection side 3a and is compatible with a third opposing contact element 12a of a third connection apparatus 13a which can be arranged on the connection side 3a, as is described below with reference to FIG. 2.

The service device 1a of the service assembly 2a may also be in the form of a device which is installed in a row, inter alia in the form of a switching device, in particular in the form of a feeder switching device for a load feeder. The feeder switching device may in this case comprise different functional units in combination, such as a contactor, an overload relay and/or a power breaker.

In addition to the variant as a feeder switching device, for example for a machine or system, a design of the service device 1a in the form of a motor starter or soft starter may be provided, the motor starter including the switching and protective functions; the soft starter also provides contactless load switching by way of at least one electronically driven power semiconductor element.

A motor circuit breaker having the functions of short-circuit protection and/or overload protection and a thermistor evaluation device for the latter protective function may likewise be provided. The service device 1a or the service assembly 2a may also be equipped with modules for controlling and/or regulating and for sending and receiving as well as for detecting and/or processing data or signals.

FIG. 2 shows an advantageous refinement of the service assembly 2b which includes the service device 1a. The service device 1a or the functional unit 9 is in this case also equipped, in addition to the contact element 4a, with the third contact element 11 on the connection side 3a. The contact element 4a corresponds to the further opposing contact element 7a of the further connection apparatus 8a, while the third contact element 11 is equipped with the third opposing contact element 12a of the third connection apparatus 13a which can be arranged on the connection side 3a such that they can be joined together so as to supplement one another. The third contact element 11 and the third opposing contact element 12c are in this case illustrated in simplified form and may of course be designed for a connection to two or more auxiliary lines 14 as shown in FIGS. 1 and 2. The auxiliary lines 14 are in each case, starting from the functional unit 9, led up to the third contact element 11 using a multi-track design.

Instead of the separate, further connection apparatus 8a and the third connection apparatus 13a, a combined connection apparatus 8c can be mechanically and electrically connected to the service device 1a by way of the associated further opposing (O contact element 7c and the third opposing contact element 12c. The third connection apparatus 13a, which is in the form of an additional module and is integrated as a connection unit in the combined connection apparatus 8c, may act as a control module and/or an alarm module and can be electrically conductively connected to the auxiliary circuit or to an auxiliary energy bus.

A suitable main current and auxiliary current feed line 10c, corresponding to the main current feed line 10a of the further connection apparatus 8a, is provided on the combined connection apparatus 8c. On the further connection side 3b of the service device 1a which lies opposite the connection side 3a, the connection apparatus 6b can likewise be arranged on the contact element 4b of the service device 1a by way of the opposing contact element 5b in accordance with the exemplary embodiment shown in FIG. 1.

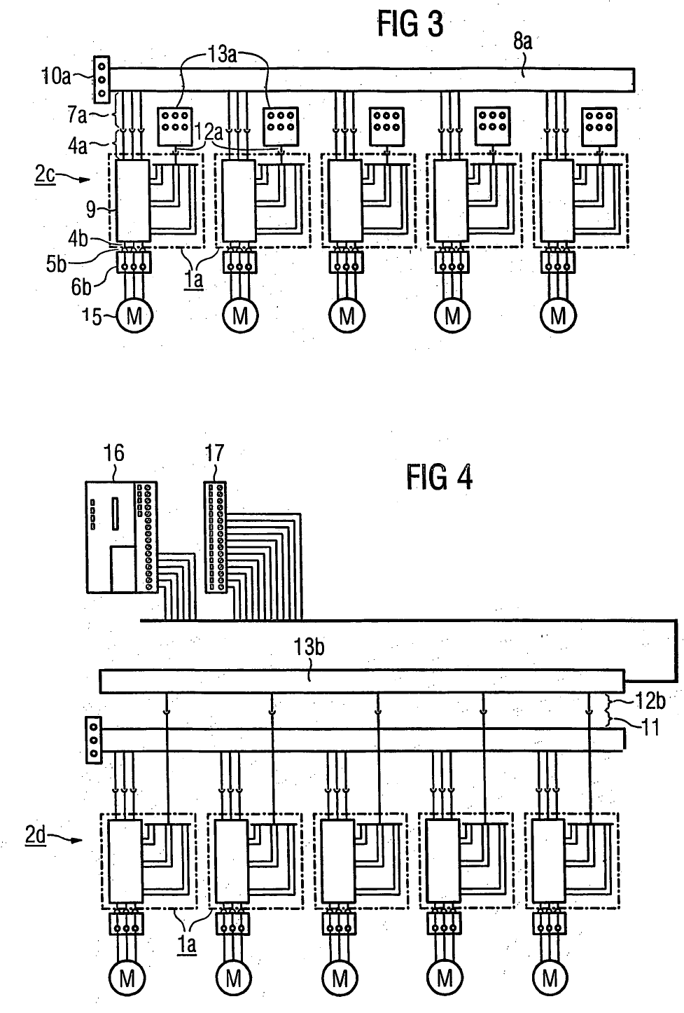

FIG. 3 shows an advantageous embodiment of the service assembly 2c in the form of a service system. The further connection apparatus 8a is designed such that, for example, two or more adjacent units of the service device 1a can be connected to the associated contact element 4a by way of opposing contact element 7a of said further connection apparatus 8a. Thus, a common power supply is provided via the main current feed line 10a. The connection apparatus 6b is in this case connected to the contact element 4b as shown in FIGS. 1 and 2, conductor for conductor, via the opposing contact element 5b of said connection apparatus 6b.

A load element, in particular a three phase motor 15, is connected to the service device 1a via corresponding lines (phases and possibly protective conductors) on an output side of the connection apparatus 6b. The functional unit 9 of the service device 1a is in this case provided, as illustrated in simplified form, for the purpose of switching at least one phase, the third connection apparatus 13a being designed per service device 1a, as shown in FIGS. 1 and 2. The same applies to the adjacent units of the service device 1a and of the respective connection apparatus 13a.

The embodiment shown in FIG. 4 of the service assembly 2d which is likewise in the form of a service system has, in contrast to the service assembly 2c, a continuous, third connection apparatus 13b, which supplies power to two or more units of the service device 1a, having a correspondingly designed, third opposing contact element 12b suitable for the respective third contact element 11 in place of the connection apparatus 13a shown in FIG. 3 which is provided for each individual service device 1a. The third connection apparatus 13b may, in at least one embodiment, advantageously be electrically and possibly mechanically connected to a controller 16, in particular to a programmable controller (SPS), and to a digital input/output assembly 17 such that an upstream control unit for signal exchange can be arranged using simple methods/devices between the individual service devices 1a in the service system.

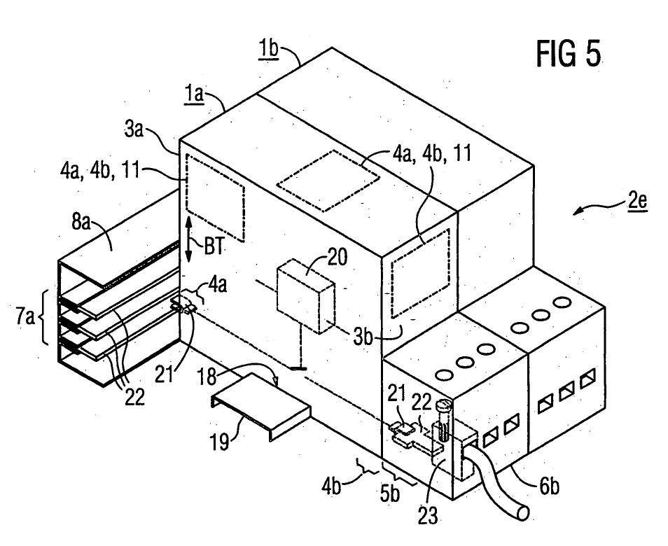

FIG. 5b shows a perspective illustration of an advantageous refinement of two adjacent service devices 1a, 1b as part of a service assembly 2e. The service devices 1a, 1b are in this case in the form of devices which are installed in a row and are fixed or snapped onto a mounting rail 19 using an accommodating element 18. The accommodating element 18 for the mounting rail 19 (also referred to as a support rail, a profiled rail or a top-hat rail) may be designed so as to correspond to the relevant accommodating apparatuses. The service device 1a in a three-phase design has (illustrated in simplified form for one phase or conductor track) the contact element 4a on the connection side 3a and the further contact element 4b on the further connection side 3b. Owing to the device design assembled in this manner of the service assembly 2e, an unaltered assembly depth BT can be achieved in the mounted state.

The contact element 4a, 4b advantageously have the same phase, i.e. are of identical design per conductor track, such that the service device 1a can be designed using the same or uniform and thus cost-effective components. Likewise illustrated in simplified form is an actuating element 20 which is based, for example, on an electromagnetic or manual operation. The actuating element 20 is part of the functional unit 9 and brings about connection or isolation of the corresponding conductor track via associated switching contacts.

In addition to the adapterless, electrical and mechanical arrangement of the connection apparatus 6b on the service device 1a, on the one hand, and the contact between the service device 1a and the further connection apparatus 8a without the use of a connection device which is matched individually to the further opposing contact element 7a, on the other hand, the connection apparatuses 6b, 8a can also be arranged on the respective other connection side 3a or 3b. Of course, the contact element 4a, 4b and the third contact element 11, corresponding to the schematic illustration, can be integrated in the service device 1a or arranged on it on opposing connection sides or connection sides which are offset at an angle.

The contact element 4a, 4b each have a contact element 21 in the form of a so-called horseshoe contact per phase or conductor track. With the aid of these fork-shaped contact elements 21, it is possible, on the one hand, to make contact with opposing contact elements 22 of the busbar-like opposing contact element 7a of the further connection apparatus 8a and with the tab- or lug-like opposing contact elements 22 of the opposing contact element 5b of the replaceable and removable connection apparatus 6b.

The opposing contact element 7a may further have an advantage, owing to their rail form, that the service devices 1a, 1b can be connected in gridless fashion, i.e. at any desired points. In addition, this type of busbar is easy to produce and can be cut to length depending on the application. The connection apparatus 6b has for its part a connection device 23 for each phase which, in accordance with the illustration, is in the form of a screw terminal for only one phase. Further embodiments of the connection device 23 in the form of spring-loaded terminals, insulation displacement contacts or plug-type terminals as well as crimping connections can likewise be used for each individual phase and/or conductor.

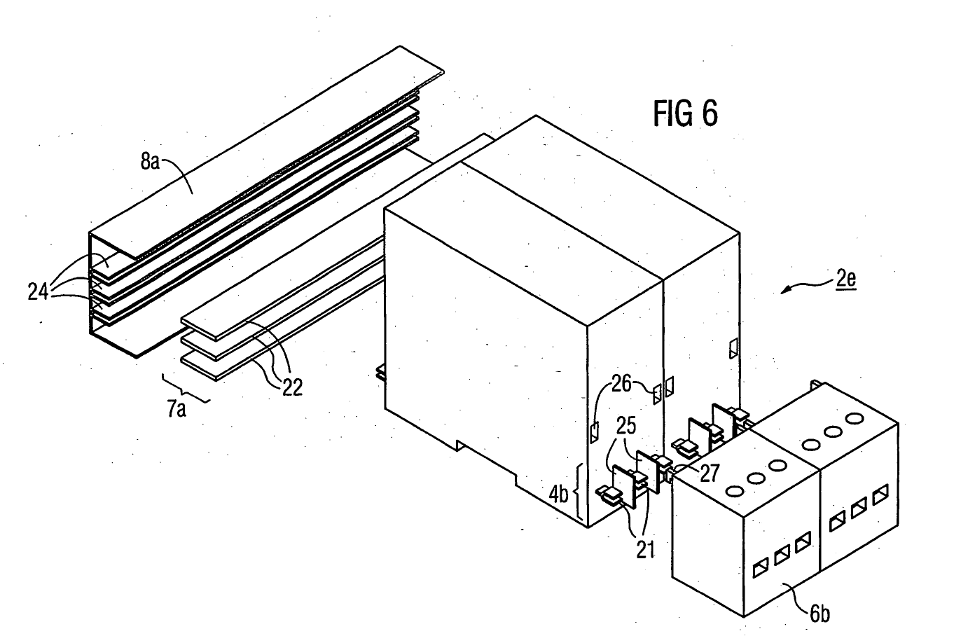

The exploded illustration shown in FIG. 6 of the service assembly 2e illustrates the design of the further connection apparatus 8a and of the further opposing contact element 7a. The opposing contact elements 22 of the opposing contact element 7a can in this case be plugged or pushed into holders 24 provided and are surrounded by said holders 24 in insulating fashion and held at a distance from one another. Insulating elements 25, which ensure the insulating distance, in particular the leakage paths and air gaps, in accordance with predeterminable requirements, are fitted between in each case two contact elements 21 of the further contact element 4b.

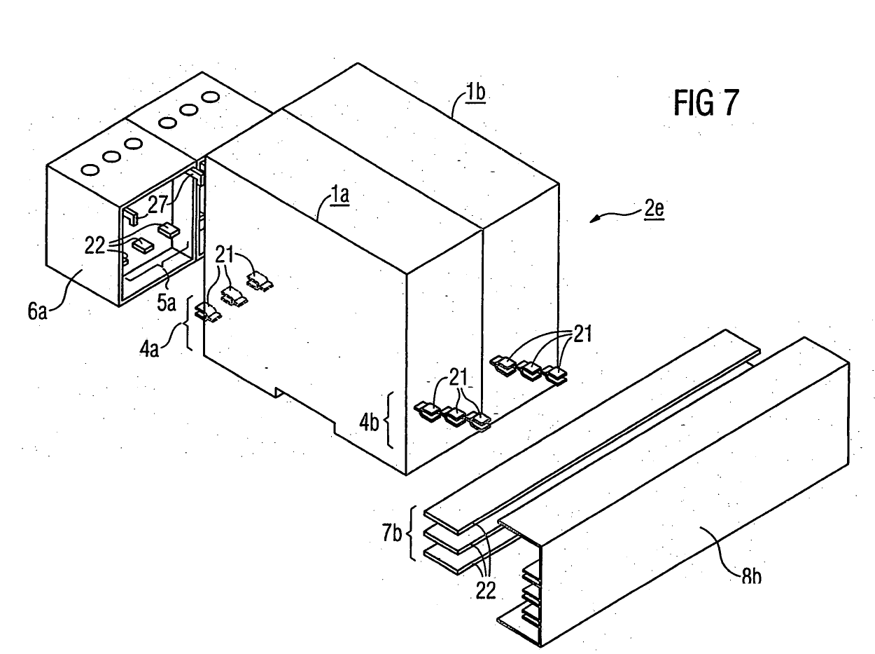

FIG. 7 also shows an exploded illustration of the service assembly 2e. In order to make contact with the further opposing contact element 7b or opposing contact elements 22 formed by the busbars, the contact elements 21 of the service devices 1a, 1b are arranged in stepped fashion and such that they are offset with respect to one another, with the result that the use of specially designed busbars, which would for their part make possible a connection to the contact elements 21, is superfluous. The opposing contact elements 22 of the opposing contact element 5a are arranged on one plane on the inside of or lying within the housing of the connection apparatus 6a, a high degree of protection against touching contact being provided.

Correspondingly, the contact element 4a, 4b are arranged on the outside of the service device 1a, i.e. in an easily accessible manner. An internal arrangement of the respective contact element 4a, 4b or an external arrangement of the opposing contact element 5a, 7b can likewise be provided depending on the application.

The service device 1a shown in FIGS. 6 and 7 is provided with a schematically illustrated holding element 26 which corresponds to a hook-like opposing piece 27 arranged on the connection apparatus 6a, 6b such that an interlocking and/or force-fitting connection results between the housings of the service device 1a and the respective connection apparatus 6a, 6b. The same may also be envisaged for the further connection apparatus 8a, 8b and also for the third connection apparatus 13a, for example shown in FIG. 5. The connection apparatuses 6a or 6b shown in FIGS. 5 to 7 are advantageously in the form of a box with a physical width which is identical to that of the service device 1a, with the result that an overall arrangement is provided based on the principle in which devices are installed in a row. The same of course also applies to the third connection apparatus 13a.

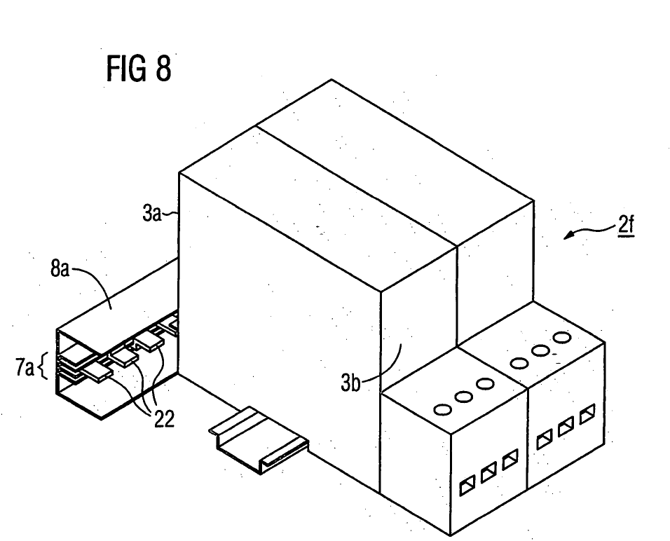

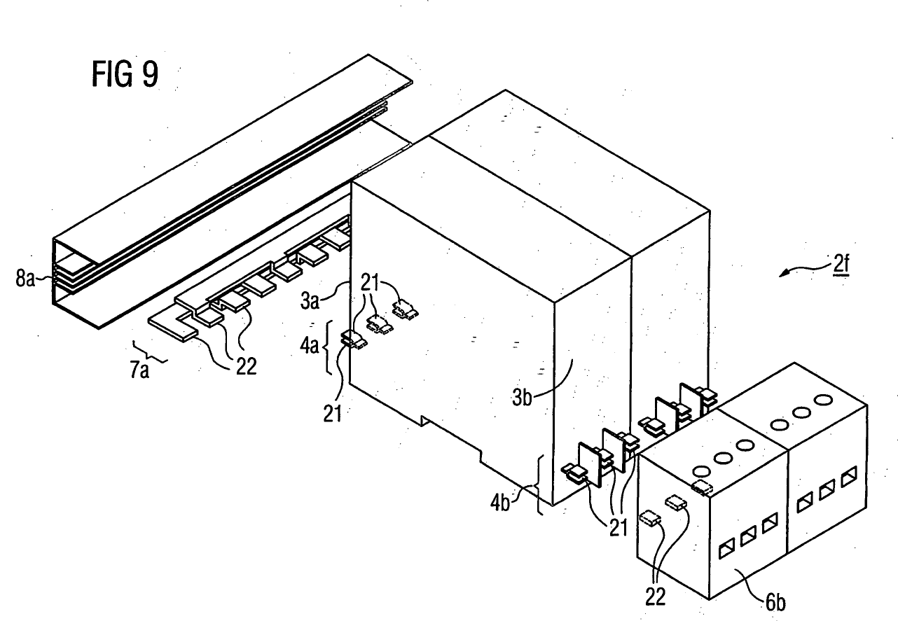

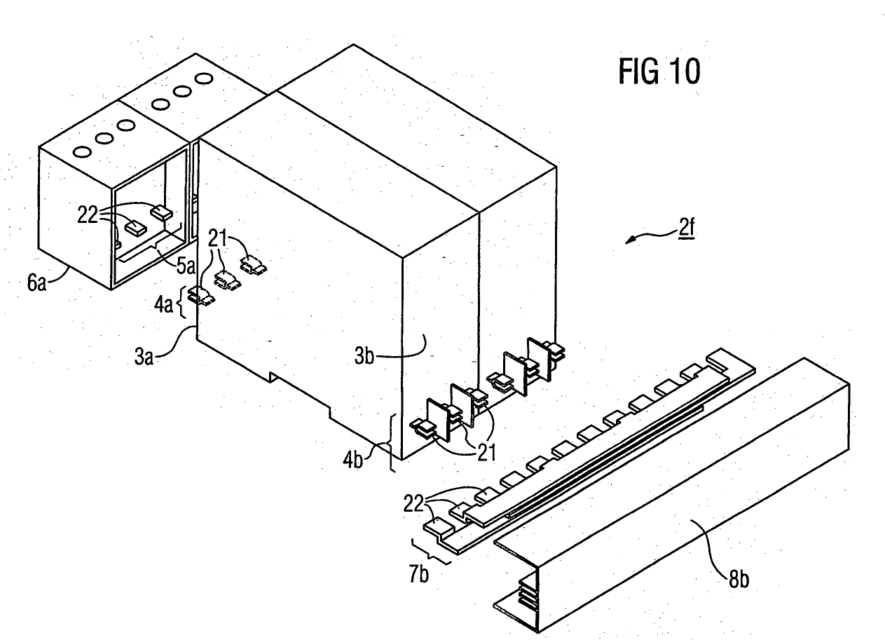

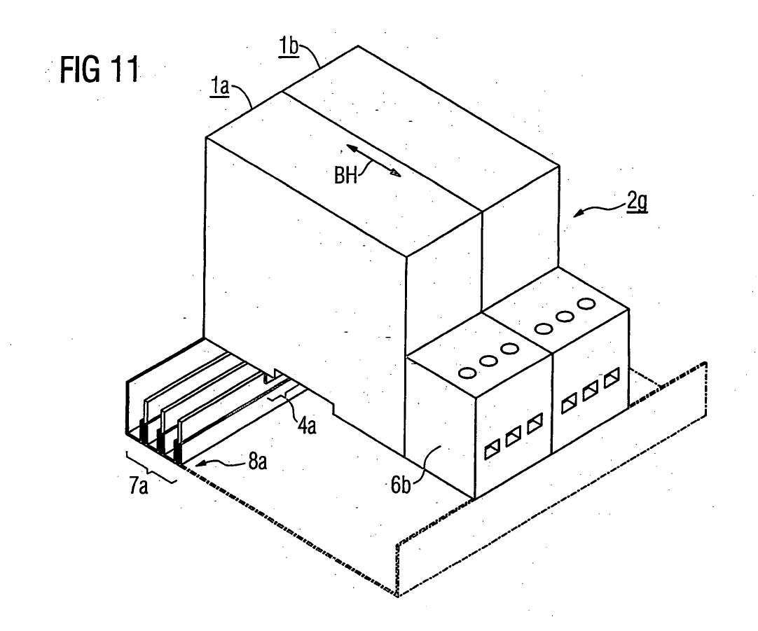

FIGS. 8 to 10 show an advantageous refinement of the service assembly 2f. The further opposing contact element 7a, 7b of the further connection apparatus 8a or 8b in this case has bent-back opposing contact elements 22 which are as a result arranged on one plane. The opposing contact elements 22 of the connection apparatus 6a, 6b are likewise arranged on one plane such that the contact elements 21 are arranged on one plane on both connection sides 3a, 3b. The contact element 4a or the further contact element 4b accordingly have an identical design.

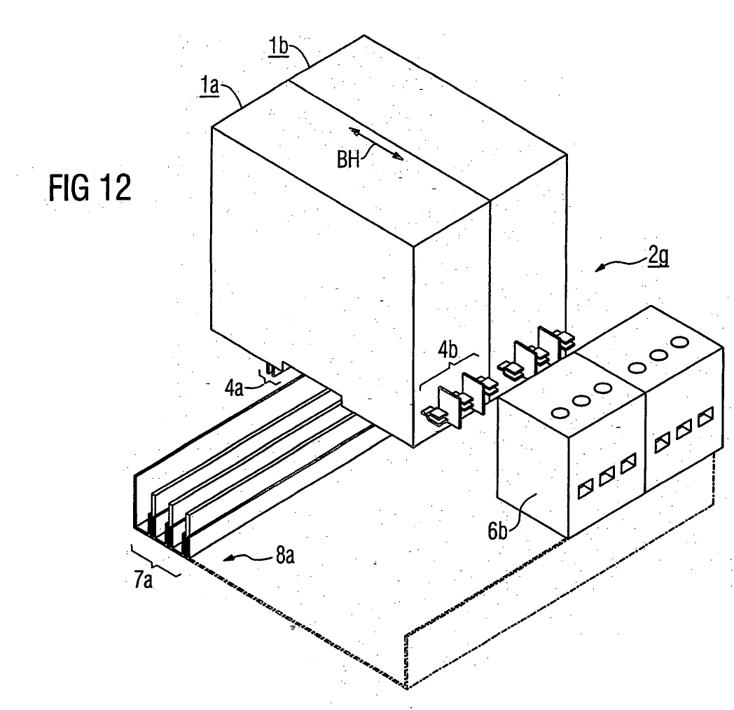

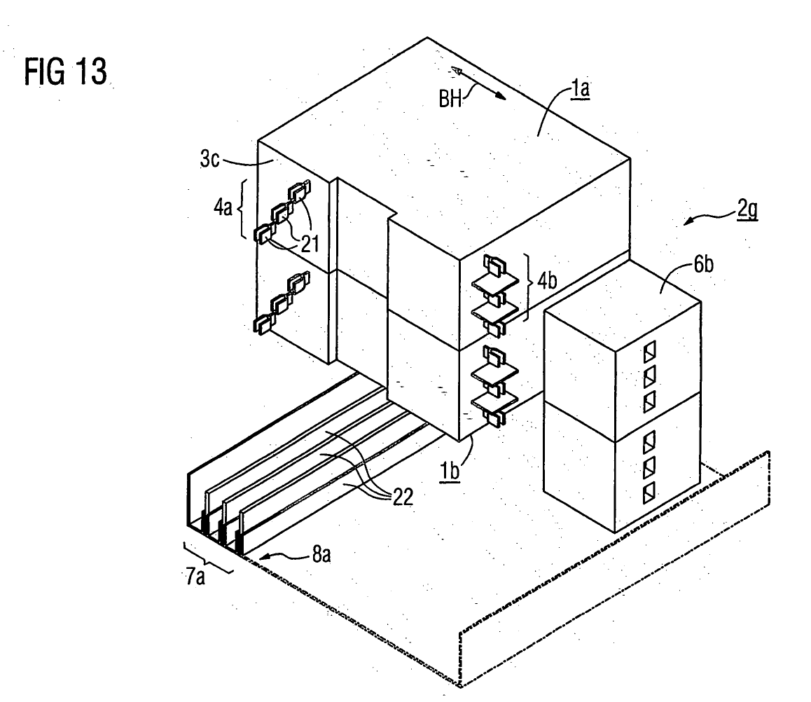

As shown in FIGS. 11 to 13, the service devices 1a, 1b which are positioned next to one another are in each case designed as part of an advantageous design for the service assembly 2g such that the contact element 4a is arranged opposite the further contact element 4b on one connection side 3c, which is offset at an angle, for example of the service device 1a.

Owing to the arrangement of the contact element 4a on an underside of the service device 1a, contact is made with the further opposing contact element 7a of the further connection apparatus 8a. This has the advantage of saving space in terms of the height of the assembly BH when the service device 1a is mounted.

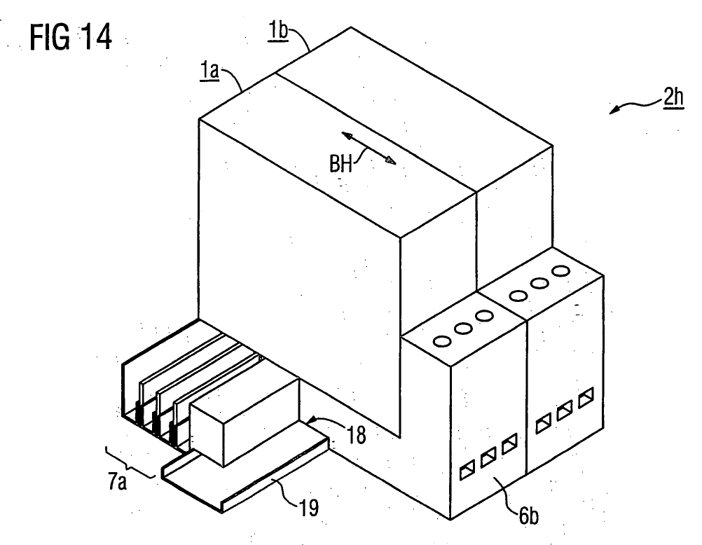

The further connection apparatus 8a is in this case in the form of a mounting device, in particular in the form of a mounting platform, for the connection apparatus 6b. A receptacle for the third connection apparatus 13a, for example, in accordance with FIG. 2 can be provided in the same manner. The trough-like, further connection apparatus 8a also serves the purpose of holding, supporting or bearing the service devices 1a, 1b, which can in this case be installed in gridless fashion, and can advantageously be preassembled, for example, in a switchgear cabinet. FIG. 13 also illustrates the fact that the contact elements 21 are arranged in stepped fashion such that they are offset with respect to one another in order to ensure that contact is made with the opposing contact elements 22 in a simple manner.

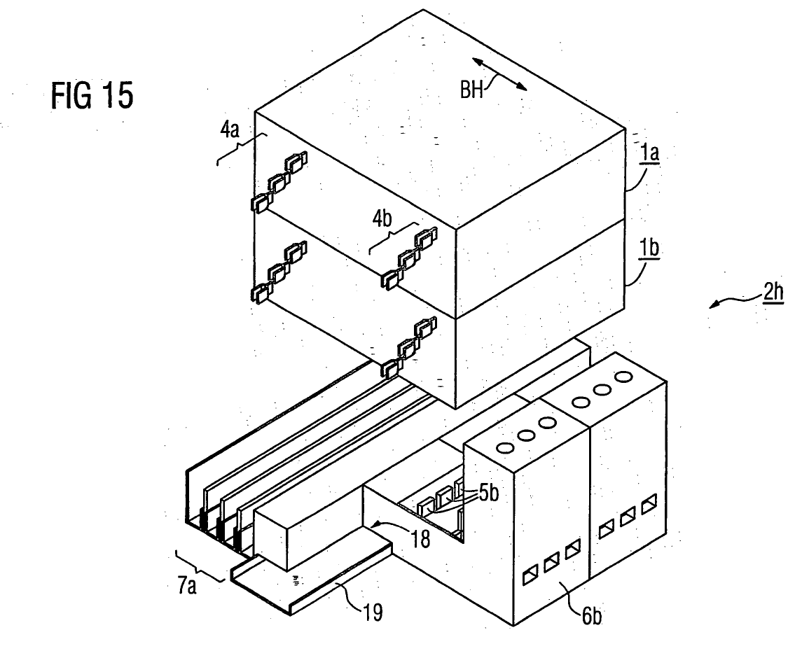

FIGS. 14 and 15 also show an advantageous embodiment of the service assembly 2h which provides a particularly space-saving design. In this case, the contact element 4a, 4b shown in FIG. 15 are arranged on a common connection side (in this case a device underside) of the service device 1a. Both the opposing contact element 5b and the further opposing contact element 7a are correspondingly aligned vertically for contact-making purposes. This results, in particular in conjunction with a bent-back design for the connection apparatus 6b, in a considerable reduction in the height of the assembly BH. The third connection apparatus 13a may also be designed to be bent back in order to achieve the advantage mentioned. The accommodating element 18 for the mounting rail 19 is advantageously integrated on the connection apparatus 6b such that easy assembly is provided even in the case of such a compact design of the service assembly 2h.

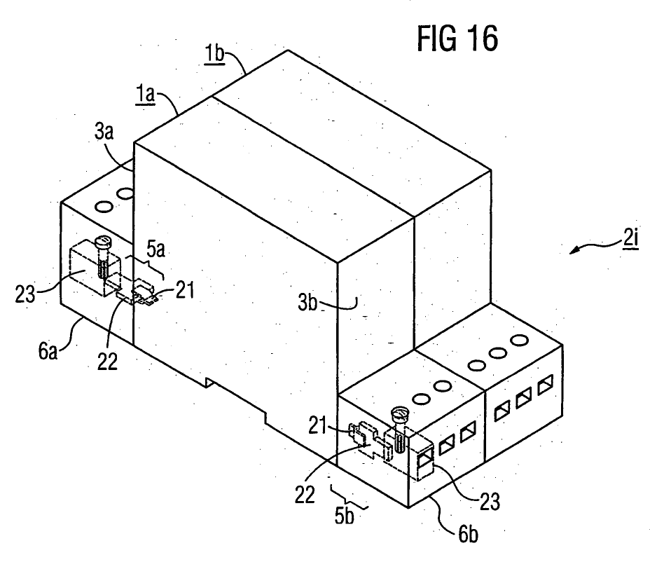

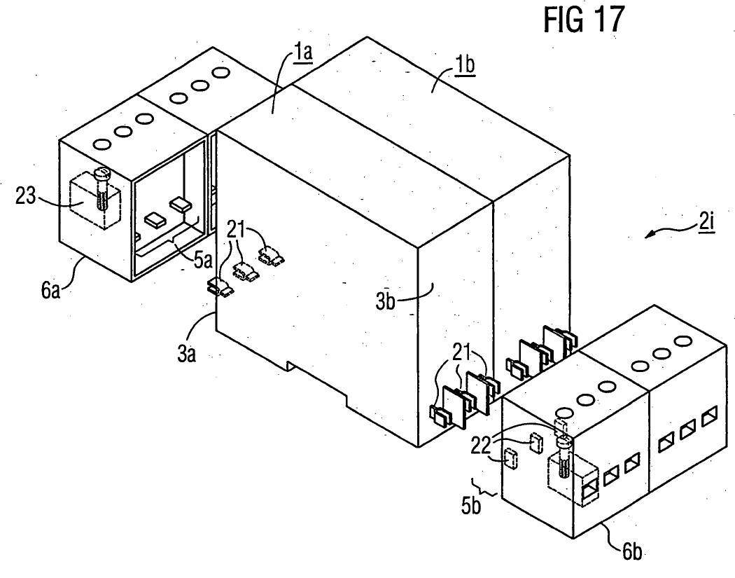

FIGS. 16 to 19 show refinements of the service assembly 2i and 2j in which in each case one of the connection apparatuses 6a or 6b can be brought into an electrically conductive connection on both connection sides 3a, 3b of the service device 1a. The connection apparatuses 6a, 6b (in this case provided with in each case a connection device 23 in the form of a screw terminal) shown in FIGS. 16 and 17 in this case differ firstly in terms of their dimensions and secondly in terms of the position of their opposing contact element 5a and 5b, respectively. They are arranged such that they are offset from one another by an angle to give reverse polarity protection such that, on the connection side 3a, contact modules having horizontally aligned opposing contact elements 22 and, on the further connection side 3b, contact modules having vertically aligned opposing contact elements 22 can be connected to the contact elements 21 which each have the same position. The fork shape which is typical for the horseshoe contact is found again on both connection sides of the service device 1a in the case of the contact elements.

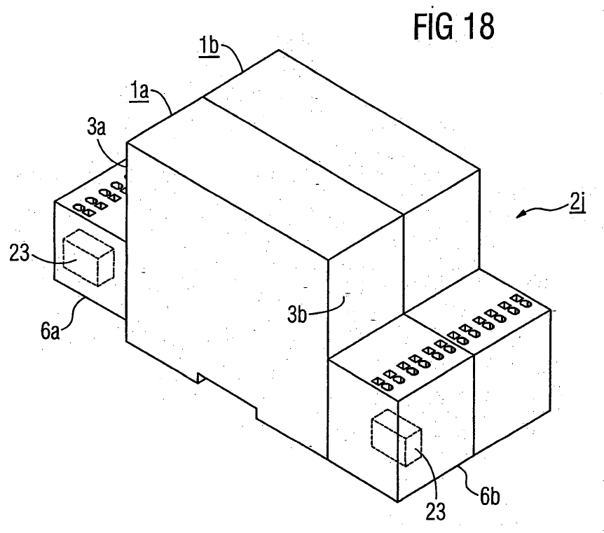

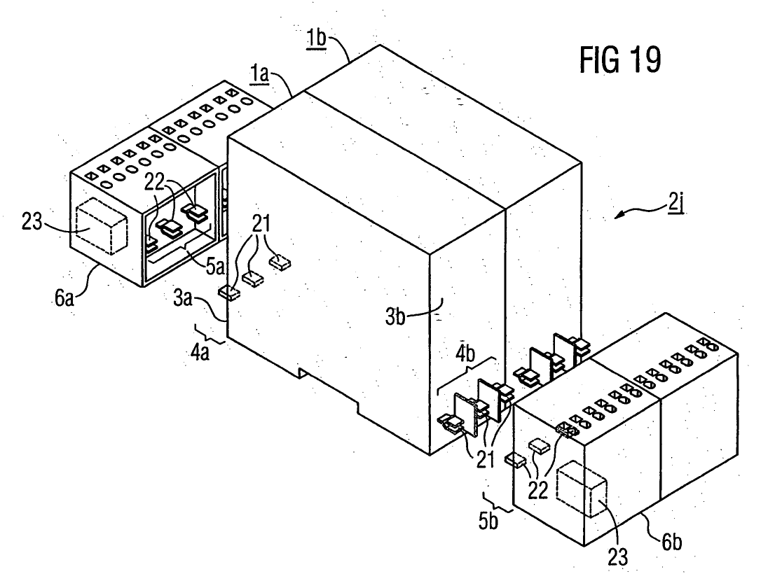

The connection apparatuses 6a, 6b, which are equipped with connection device 23 in the form of spring-loaded terminals, as shown in FIGS. 18 and 19 differ firstly likewise in terms of their dimensions and secondly in terms of the design of their opposing contact element 5a and 5b, respectively. In this case, the opposing contact element 5a has the three opposing contact elements 22 which are arranged next to one another on one plane and are in the form of a horseshoe contact. Correspondingly, the contact elements 21 of the contact element 4a on the connection side 3a are in the form of contact lugs. On the opposing, further connection side 3b, the contact elements 21 of the contact element 4b are designed, for example, so as to correspond to FIG. 6 such that, in accordance with this embodiment as well, reverse polarity protection is provided by contact or opposing contact elements 21 or 22 having different phases.

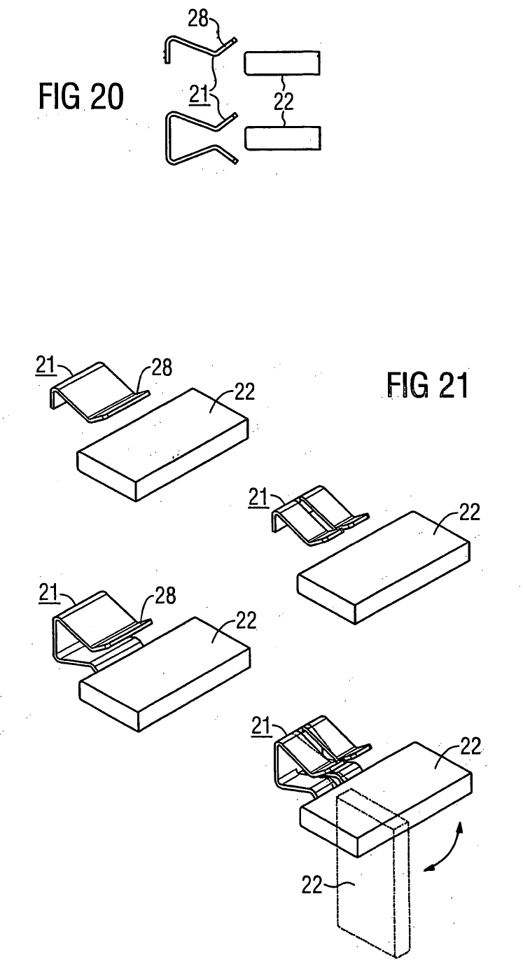

FIGS. 20 and 21 show schematic and, respectively, perspective illustrations of the contact elements 21 and the opposing contact elements 22, irrespectively. In this case, the contact elements 21 and the opposing contact elements 22 are approximately S-shaped in a first refinement and fork-shaped in a second refinement. Both variants are designed such that an appropriate contact force is provided via a definable prestress in the form of a spring contact.

Owing to the division resulting from the slots which are introduced, for example in the S-shaped or fork-shaped contact elements 21 and the resulting duplication of the spring contacts per contact element 21, the current-carrying capacity is advantageously increased with the same, relatively low contact force. Furthermore, a cross fork-shaped or else cross slot-shaped design of the contact element 21 or of the opposing contact element 22 is shown such that the respective other element can optionally be inserted horizontally or vertically.

In order to compensate for a height offset, which may be provided, of one of the contact elements 21 with respect to one of the corresponding opposing contact elements 22 and in order to make insertion easier in the sense of making contact, at least one inclined bevel 28 on the free end side is provided per contact or opposing contact element 21 or 22.

Embodiments of the invention explained above can be summarized as follows:

In order to specify a service device 1a, 1b and a service assembly 2a-2j having at least one service device 1a, 1b which are suitable, on the one hand, for using different connection techniques and, on the other hand, for being incorporated in different wiring systems, provision is made for the service device 1a, 1b to be provided on one connection side 3a-3c with a contact element 4a, 4b which is compatible both with an opposing contact element 5a, 5b of a connection apparatus 6a, 6b which can be arranged on the connection side 3a-3c and with a further opposing contact element 7a, 7b of a further connection apparatus 8a, 8b which can be arranged on the connection side 3a-3c, but is different than the connection apparatus 6a, 6b.

Owing to the design of the contact element 5a, 5b which is compatible with the opposing contact element 5a, 5b or 7a, 7b, contact can be made with firstly diverse connection apparatuses 6a, 6b in the form of contact modules and secondly diverse further connection apparatuses 8a, 8b in the form of contact rail systems on the service device 1a, 1b, which can be equipped with different, yet standardized functional units 9, without the use of integrated connection units or adapters forming interfaces, i.e. directly to the respective functional unit 9 of the corresponding service device 1a, 1b.

In this case, in addition to the connection apparatuses 6a, 6b or 8a, 8b, the contact rail systems for various service devices 1a, 1b may also be standardized as part of the service assembly 2a-2j, with the result that in total a design is provided having reduced costs. The diverse features of the functional units 9 (for example currents, voltages, setting ranges or the like) or the connection apparatuses 6a, 6b and 8a, 8b (a plurality of connection techniques) are advantageously restricted to the respective unit or apparatus. In addition, common contact is made with the functional unit 9 of the service device 1a, 1b via the interface of the control or alarm circuit by way of the contact modules or the contact rail system, an associated signal path either being led into the contact module and/or into the contact rail system such that a combination is made possible when passing on the signals.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A service device, comprising:
a contact element on one connection side, compatible both with an opposing contact element of a connection apparatus arrangeable on the connection side and with a further opposing contact element, different than the opposing contact element, of a further connection apparatus arrangeable on the connection side (3a).

2. The service device as claimed in claim 1, further comprising
a further contact element, provided on a further connection side and compatible with at least one of the opposing contact element of the connection apparatus arrangeable on the further connection side and with the further opposing contact element of the further connection apparatus arrangeable on the further connection side.

3. The service device as claimed in claim 2,
further comprising at least one third contact element, provided on one connection side and compatible with a third opposing contact element of a third or combined connection apparatus, arrangeable on the one connection side.

4. The service device as claimed in claim 2, having an arrangement of the contact element and the further contact element on a common connection side.

5. The service device as claimed in claim 2, having an arrangement of the contact element and the further contact element on opposing connection sides or connection sides which are offset at an angle.

6. The service device as claimed in claim 3, having a design of at least one of the contact element, the further contact element and the third contact element having in each case at least one contact element per conductor track provided on the device side.

7. The service device as claimed in claim 6,
having a uniform and physically identical design of the contact elements at least on one connection side.

8. The service device as claimed in claim 6,
having a step-like, mutually offset arrangement of the contact elements on at least one connection side.

9. The service device as claimed in claim 6, having at least one of a fork-shaped and cross fork-shaped design of the respective contact element.

10. The service device as claimed in claim 6, having an approximately S-shaped design of the respective contact element.

11. The service device as claimed in claim 9,
having at least one inclined bevel on the free end side per contact element.

12. The service device as claimed in claim 6, having in each case an isolating element between two contact elements.

13. The service device as claimed in claim 1, having a holding device for the connection apparatus.

14. The service device as claimed in claim 1, having an accommodating device for a mounting rail.

15. A service assembly, comprising:
at least one service device provided on one connection side with a contact element and on a further connection side with a further contact element;
a connection apparatus arrangeable on the one connection side and including an opposing contact element compatible with the contact element; and
a further connection apparatus, arrangeable on the further connection side and including a further opposing contact element different than the opposing contact element and compatible with the further contact element.

16. The service assembly as claimed in claim 15, further comprising:
at least one third contact element, provided on one connection side and compatible with a third opposing contact element of a third or combined connection apparatus, arrangeable on the one connection side.

17. The service assembly as claimed in claim 15,
having at least one of a design of the connection apparatus in the form of a contact module for a load element, connectable thereto and a design of the further connection apparatus in the form of a contact rail system for a main circuit.

18. The service assembly as claimed in claim 16,
having a design of the third or combined connection apparatus in the form of an additional module for at least one of a control and alarm circuit.

19. The service assembly as claimed in claim 15, further comprising
one holding device on the service device for the connection apparatus.

20. The service assembly as claimed in claim 15,
having a design of the further connection apparatus in the form of a mounting device for the connection apparatus.

21. The service assembly as claimed in claim 15,
having a design of the connection apparatus which is identical in terms of physical width to the service device.

22. The service assembly as claimed in claim 15,
having at least one of a box-shaped and bent-back design of the connection apparatus.

23. The service device as claimed in claim 1, having an arrangement of the contact element on a common connection side of the service device.

24. The service assembly as claimed in claim 1, having an arrangement of the contact element on at least one of opposing connection sides of the service device and on connection sides of the service device which are offset at an angle.

25. The service assembly as claimed in claim 1, having an external arrangement of the contact element on the service device.

26. The service assembly as claimed in claim 1, having an internal arrangement of the opposing contact element on the connection apparatus.

27. The service assembly as claimed in claim 15, at least one of having a design of the contact element having at least one contact element per conductor track provided on the device side and having a design of the opposing contact element having at least one opposing contact element per conductor track provided on the apparatus side.

28. The service assembly as claimed in claim 17, having opposing contact elements arranged on the contact rail system of the further connection apparatus.

29. The service assembly as claimed in claim 17, having opposing contact elements formed such that they are bent back on the contact rail system of the further connection apparatus.

30. The service assembly as claimed in claim 27, having a uniform or mutually physically identical design of the contact elements at least on one connection side of the service device or the opposing contact elements of the respective connection apparatus.

31. The service assembly as claimed in claim 27, having a step-like, mutually offset arrangement of the contact elements on at least one connection side of the service device or of the opposing contact elements of the respective connection apparatus.

32. The service assembly as claimed in claim 27, having a fork-shaped or cross fork-shaped design of the respective contact element or of the respective opposing contact element.

33. The service assembly as claimed in claim 27, having an approximately S-shaped design of the respective contact element or of the respective opposing contact element.

34. The service assembly as claimed in claim 32, having at least one inclined bevel on the free end side per contact element or per opposing contact element.

35. The service assembly as claimed in claim 27, having in each case one isolating element between two contact elements or between two opposing contact elements.

36. The service assembly as claimed in claim 15, having connection devices, provided at least on one of the connection apparatuses, for conductors which can be connected thereto.

37. The service assembly as claimed in claim 15, having an accommodating device for a mounting rail on at least the one service device or on one of the connection apparatuses.

38. The service device as claimed in claim 3, having an arrangement of the contact element and at least one of the further contact element and the third contact element on a common connection side.
